(19) United States
(12) Patent Application Publication
(10) Pub. No.: US 2025/0366079 A1
(43) Pub. Date: Nov. 27, 2025

(54) QUANTUM COMPUTING SEMICONDUCTOR DEVICE AND METHODS OF FORMATION

(71) Applicant: Taiwan Semiconductor Manufacturing Company, Ltd., Hsinchu (TW)

(72) Inventors: Iuliana RADU, Zhubei City (TW); Hung-Li CHIANG, Taipei City (TW); Hung-Chi HAN, Hsinchu (TW); Jer-Fu WANG, Taipei City (TW); Goutham ARUTCHELVAN, Hsinchu County (TW); Chao-Ching CHENG, Hsinchu City (TW)

(21) Appl. No.: 18/672,526

(22) Filed: May 23, 2024

(51) Int. Cl. H01L 29/66; G06N 10/40; H01L 21/8238; H01L 27/092; H01L 29/08; H01L 29/423; H01L 29/786

(52) U.S. Cl. CPC H10D 48/383; G06N 10/40; H10D 30/6735; H10D 30/6757; H10D 62/151; H10D 84/017; H10D 84/0172; H10D 84/038; H10D 84/85

(57) ABSTRACT

Qubits in a quantum computing semiconductor device may be arranged in a two-dimensional array. The two-dimensional array may be implemented using fin-based semiconductor manufacturing techniques. For example, a first active semiconductor region (e.g., a first fin structure) may extend in a first direction and a second active semiconductor region (e.g., a second fin structure) may extend in a second direction. A qubit may be located an intersection point between the first active semiconductor region and the second semiconductor region. This enables qubits to be formed in a grid in the two-dimensional array, which provides greater qubit density and shorter distances between qubits (and thus, greater quantum computing performance) compared to one-dimensional (e.g., linear) qubit arrays. Moreover, implementing qubits using fin-based semiconductor manufacturing techniques enables quantum computing arrays to be integrated on the same semiconductor device as other complementary metal-oxide semiconductor (CMOS) integrated circuits.

### BACKGROUND

Quantum computing involves computation systems that use quantum mechanical phenomena to manipulate data. Quantum computing may involve initializing states of N qubits (quantum bits), creating controlled entanglements among the N qubits, allowing these states to evolve, and reading out the states of the N qubits after the evolution. A qubit is a system having two degenerate (e.g., of equal energy) quantum states, with a non-zero probability of being found in either state. Thus, N qubits can define an initial state that is a combination of 2^{N} classical states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example quantum computing semiconductor device described herein.

FIGS. 2A-2L are diagrams of an example of forming the quantum computing semiconductor device described herein.

FIG. 3 is a flowchart of an example process associated with forming the quantum computing semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A quantum computing semiconductor device may include a plurality of qubits implemented in semiconductor-based structures. For example, a plurality of qubits may be arranged in a linear array along an active semiconductor region. Adjacent qubits are electrically separated by barrier gates, and plunger contacts coupled with each qubit may be used to control the quantum states for the qubits. An electron may be provided from a source side of the active semiconductor region and trapped in a qubit between adjacent barrier gates, and the spin of the electron may be modified through spin polarization. The direction of the spin of the electron may correspond to a quantum computation associated with the qubit. The spin states of the qubits along the linear array are entangled and accumulated at an accumulation side of the semiconductor active region.

In some implementations described herein, qubits in a quantum computing semiconductor device are arranged in a two-dimensional array. The two-dimensional array may be implemented using fin-based semiconductor manufacturing techniques. For example, a first active semiconductor region (e.g., a first fin structure) may extend in a first direction and a second active semiconductor region (e.g., a second fin structure) may extend in a second direction. A qubit may be located an intersection point between the first active semiconductor region and the second semiconductor region. This enables qubits to be formed in a grid in the two-dimensional array, which provides greater qubit density and shorter distances between qubits (and thus, greater quantum computing performance) compared to one-dimensional (e.g., linear) qubit arrays. Moreover, implementing qubits using fin-based semiconductor manufacturing techniques enables quantum computing arrays to be integrated on the same semiconductor device as other complementary metal-oxide semiconductor (CMOS) integrated circuits.

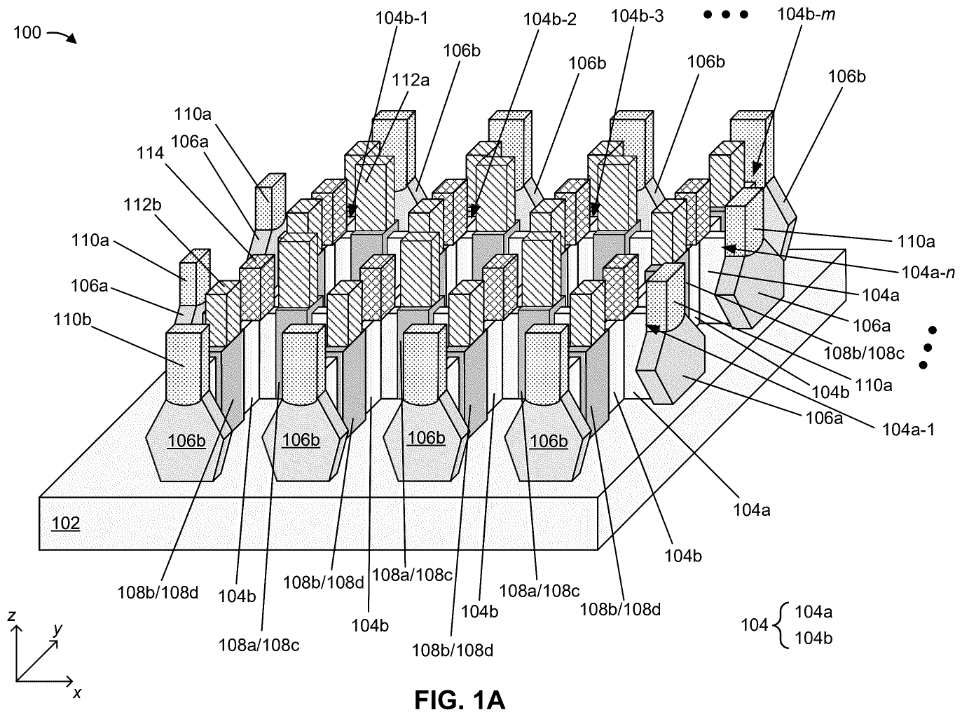

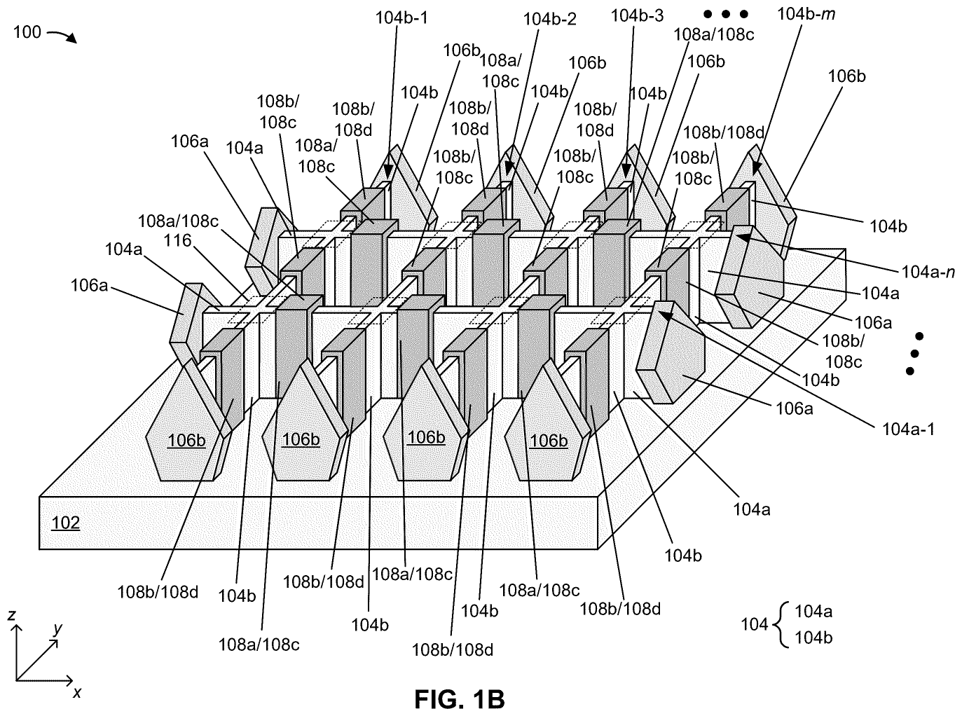

FIGS. 1A and 1B are diagrams of an example quantum computing semiconductor device 100 described herein. FIGS. 1A and 1B illustrate perspective views of the quantum computing semiconductor device 100.

As shown in FIG. 1A, the quantum computing semiconductor device 100 includes a substrate 102 and a fin grid 104 extending above the substrate 102. The substrate 102 may include a semiconductor substrate, such as a silicon (Si) substrate, a germanium (Ge) substrate, a silicon germanium (SiGe) substrate, and/or another type of semiconductor substrate from which the fin grid 104 may be formed.

The fin grid 104 includes a first plurality of fin structures 104a and a second plurality of fin structures 104b. An unobstructed view of the fin grid 104, including the fin structures 104a and 104b, is illustrated in FIG. 1B. The fin structures 104a and 104b of the fin grid 104 may correspond to the active regions of the quantum computing array of the quantum computing semiconductor device 100.

The fin structures 104a and 104b of the fin grid 104 may be formed from the substrate 102 such that the fin structures 104a and 104b of the fin grid 104 include the same semiconductor material (or semiconductor material composition) as the substrate 102. Additionally and/or alternatively, the fin structures 104a and 104b of the fin grid 104 may include one or more doped semiconductor materials. For example, the fin structures 104a and 104b of the fin grid 104 may include silicon (Si) and/or another semiconductor material doped with one or more n-type dopants and/or doped with one or more p-type dopants. Examples of such p-type dopants include boron (B) or germanium (Ge), among other examples. Examples of such n-type dopants include phosphorous (P) or arsenic (As), among other examples.

The fin structures 104a extend in a first direction (e.g., an x-direction) in the quantum computing semiconductor device 100, and are arranged in a second direction (e.g., a y-direction) in the quantum computing semiconductor device 100. The fin structures 104a extend above the substrate 102 in a third direction (e.g., a z-direction) in the quantum computing semiconductor device 100.

The fin structures 104b extend in the second direction (e.g., the y-direction) in the quantum computing semiconductor device 100, and are arranged in the first direction (e.g., a x-direction) in the quantum computing semiconductor device 100. The fin structures 104b extend above the substrate 102 in the third direction (e.g., a z-direction) in the quantum computing semiconductor device 100.

Each fin structure 104a may intersect with each of the fin structures 104b, and each fin structure 104b may intersect with a fin structure 104a, to form the fin grid 104. The intersection points between the fin structures 104a and the fin structures 104b in the fin grid 104 correspond to qubit regions of the quantum computing array of the quantum computing semiconductor device 100. Forming qubit regions at the intersection points in the fin grid 104 enables qubit regions to be arranged in a two-dimensional array in the quantum computing array, where qubit regions are arranged in first rows in the first direction (e.g., the x-direction) and in second rows in the second direction (e.g., the y-direction).

The qubit regions at the intersection points between the fin structures 104a and the fin structures 104b in the fin grid 104 may be configured to trap one or more electrons so that the one or more properties of the electron(s), such as the spin of the electron(s), may be manipulated or modified for performing quantum computing operations in the quantum computing array. A first plurality of source/drain regions 106a may be located at ends of the fin structures 104a, and a second plurality of source/drain regions 106b may be located at ends of the fin structures 104b. The source/drain regions 106a may be configured to provide a flow of electrons through the fin structures 104a and to the qubit regions at the intersection points between the fin structures 104a and the fin structures 104b. The source/drain regions 106b may be configured to provide a flow of electrons through the fin structures 104b and to the qubit regions at the intersection points between the fin structures 104a and the fin structures 104b.

“Source/drain region” refers to a source region, a drain region, or both a source and a drain region, depending on the context. In some implementations, the source/drain regions 106a located at first ends of the fin structures 104a are source regions through which electrons are provided to the fin structures 104a, and the source/drain regions 106a located at second ends of the fin structures 104a opposing the first ends are drain regions or accumulation regions that are used to measure the electrons that are trapped in the qubit regions. Similarly, the source/drain regions 106b located at first ends of the fin structures 104b are source regions through which electrons are provided to the fin structures 104b, and the source/drain regions 106b located at second ends of the fin structures 104b opposing the first ends are drain regions or accumulation regions that are used to measure the electrons that are trapped in the qubit regions.

The source/drain regions 106a and 106b may each include a semiconductor material such as a silicon (Si), germanium (Ge), silicon germanium (SiGe), and/or another type of semiconductor material. In some implementations, the source/drain regions 106a and/or 106b each include one or more doped semiconductor materials. For example, the source/drain regions 106a and/or 106b may each include silicon (Si) and/or another semiconductor material doped with one or more n-type dopants and/or doped with one or more p-type dopants. Examples of such p-type dopants include boron (B) or germanium (Ge), among other examples. Examples of such n-type dopants include phosphorous (P) or arsenic (As), among other examples. In some implementations, the source/drain regions 106a and/or 106b include an electrically conductive material such as tungsten (W), cobalt (Co), ruthenium (Ru), and/or titanium (Ti), among other examples.

As further shown in FIG. 1A, a first plurality of gate structures 108a are included on the fin structures 104a, and a second plurality of gate structures 108b are included on the fin structures 104b. Each gate structure 108a may wrap around at least three sides of a fin structure 104a, and each gate structure 108b may wrap around at least three sides of a fin structure 104b.

Respective sets of two or more gate structures 108a are included on each of the fin structures 104a. For example, a first set of gate structures 108a is included on a first fin structure 104a-1, a second set of gate structures 108a is included on a second fin structure 104a-n, and so on. One or more of the gate structures 108a formed on a fin structure 104a-1 may be located between a first intersection point 116 between the fin structure 104a and a first fin structure 104b-1 and a second intersection point 116 between the fin structure 104a-1 and a second fin structure 104b-2. In other words, one or more of the gate structures 108a formed on a fin structure 104a may be located between adjacent intersection points 116 between the fin structure 104a and two of the fin structures 104b. In some implementations, one or more of the gate structures 108a formed on a fin structure 104a are located between an intersection point 116 and an end of the fin structure 104a.

The gate structures 108b may be formed such that each of a plurality of sets of gate structures 108b is formed on a respective fin structure 104b. For example, a first set of gate structures 108b may be formed on a first fin structure 104b, a second set of gate structures 108b may be formed on a second fin structure 104b, and so on. One or more of the gate structures 108b formed on a fin structure 104b may be located between a first intersection point 116 between the fin structure 104b and a first fin structure 104a and a second intersection point 116 between the fin structure 104b and a second fin structure 104a. In other words, one or more of the gate structures 108b formed on a fin structure 104b may be located between adjacent intersection points 116 between the fin structure 104b and two of the fin structures 104a. In some implementations, one or more of the gate structures 108b formed on a fin structure 104b are located between an intersection point 116 and an end of the fin structure 104b.

The gate structures 108a and 108b that are located between two or more intersection points in the fin grid 104 may be referred to as barrier gate structures 108c. For example, gate structures 108a that are located between two or more intersection points in the fin grid 104 may be referred to as barrier gate structures 108a/108c. As another example, gate structures 108b that are located between two or more intersection points in the fin grid 104 may be referred to as barrier gate structures 108b/108c. The barrier gate structures 108c may be included to control the flow of electrons between intersection points, thereby enabling electrons to become trapped at the qubit regions at the intersection points. The gate structures 108a located between an intersection point and a source/drain region 106a, and the gate structures 108b located between an intersection point and a source/drain region 106b, may be referred to as accumulation gates 108d. For example, gate structures 108a that are located between an intersection point and a source/drain region 106a may be referred to as accumulation gate structures 108a/108d. As another example, gate structures 108b that are located between an intersection point and a source/drain region 106b may be referred to as barrier gate structures 108b/108d. The accumulation gates 108d enable the qubit regions to be selectively measured or sampled at the source/drain regions 106a and/or 106b.

In some implementations, the gate structures 108a and 108b each include a polysilicon material that is doped with one or more types of dopants. For example, the gate structures 108a and/or 108b may each include polysilicon that is doped with one or more p-type dopants. Examples of such p-type dopants include boron (B) or germanium (Ge), among other examples. As another example, the gate structures 108a and/or 108b may each include polysilicon that is doped with one or more n-type dopants. Examples of such n-type dopants include phosphorous (P) or arsenic (As), among other examples. In some implementations, the gate structures 108a each include polysilicon that is doped with one or more p-type dopants, and the gate structures 108b each include polysilicon that is doped with one or more n-type dopants. In some implementations, the gate structures 108a each include polysilicon that is doped with one or more n-type dopants, and the gate structures 108b each include polysilicon that is doped with one or more p-type dopants. In some implementations, the gate structures 108a and the gate structures 108b each include polysilicon that is doped with the same dopant type.

Additionally and/or alternatively, the gate structures 108a and/or 108b may each include metal gate structures that include one or more metal-containing materials such as tungsten (W), cobalt (Co), ruthenium (Ru), titanium (Ti), titanium nitride (TiN), and/or aluminum (Al), among other examples. In these implementations, the gate structures 108a and/or 108b may each include one or more work function metals for tuning the work function of the gate structures 108a and/or 108b.

As further shown in FIG. 1A, source/drain contacts 110a may be included on, and electrically coupled with, the source/drain regions 106a. Similarly, source/drain contacts 110b may be included on, and electrically coupled with, the source/drain regions 106b. The source/drain contacts 110a and 110b may each include one or more metal-containing materials such as tungsten (W), cobalt (Co), ruthenium (Ru), titanium (Ti), copper (Cu), titanium nitride (TiN), and/or aluminum (Al), among other examples. In some implementations, a metal silicide layer such as titanium silicide (TiSiₓ) may be included between the source/drain regions 106a and the source/drain contacts 110a to enable a low contact resistance to be achieved between the source/drain regions 106a and the source/drain contacts 110a. In some implementations, a metal silicide layer such as titanium silicide (TiSiₓ) may be included between the source/drain regions 106b and the source/drain contacts 110b to enable a low contact resistance to be achieved between the source/drain regions 106b and the source/drain contacts 110b.

Gate contacts 112a may be included on, and electrically coupled with, the gate structures 108a. The gate structures 108a may be electrically operated through the gate contacts 112a. Similarly, gate contacts 112b may be included on, and electrically coupled with, the gate structures 108b. The gate structures 108b may be electrically operated through the gate contacts 112b. The gate contacts 112a and 112b may each include one or more metal-containing materials such as tungsten (W), cobalt (Co), ruthenium (Ru), titanium (Ti), copper (Cu), titanium nitride (TiN), and/or aluminum (Al), among other examples.

Plunger contacts 114 may be included on, and electrically coupled with, the intersection points 116 of the fin grid 104. The plunger contacts 114 may be used to modify one or more properties of the electron(s) trapped in the qubit regions at the intersection points 116. For example, a plunger contact 114 may be used to modify the quantum states of electron(s) trapped in a qubit region at an intersection point 116 above the plunger contact 114. Voltage biases may be applied to the plunger contacts 114 to modify or select the difference in energy levels associated with different spin orientations of the electrons trapped in the qubit regions. In this way, quantum computation operations may be performed in the quantum computing array of the quantum computing semiconductor device 100 by modifying (e.g., alternating) the magnetic fields at the intersection points 116 to rotate the spin of the electrons trapped in the qubit regions. The plunger contacts 114 may each include one or more metal-containing materials such as tungsten (W), cobalt (Co), ruthenium (Ru), titanium (Ti), platinum (Pt), copper (Cu), titanium nitride (TiN), and/or aluminum (Al), among other examples.

FIG. 1B illustrates the fin grid 104 with the source/drain contacts 110a and 110b, the gate contacts 112a and 112b, and the plunger contacts 114 omitted for purposes of clarity. As shown in FIG. 1B, each fin structure 104a intersects with one or more fin structures 104b at intersection point(s) 116, and each fin structure 104b intersects with one or more fin structures 104a at intersection point(s) 116. The intersection points 116 of the fin grid 104 may correspond to the locations of qubit regions of the quantum computing array of quantum computing semiconductor device 100. The plunger contacts 114 are located above the intersection points 116 to control one or more properties of the qubit regions, such as the differences in quantum states associated with the spin of the electron(s) trapped in the qubit regions.

As further shown in FIG. 1B, respective pairs of source/drain regions 106a may be located at opposing ends of the fin structures 104a, including the fin structure 104a-1 through the fin structure 104a-n. For example, a first pair of source/drain regions 106a may be located at opposing ends of the fin structure 104a-1, a second pair of source/drain regions 106a may be located at opposing ends of the fin structure 104a-2, a third pair of source/drain regions 106a may be located at opposing ends of the fin structure 104a-3, and so on.

Similarly, respective pairs of source/drain regions 106b may be located at opposing ends of the fin structures 104b, including the fin structure 104b-1 through the fin structure 104a-m. For example, a first pair of source/drain regions 106b may be located at opposing ends of the fin structure 104b-1, a second pair of source/drain regions 106b may be located at opposing ends of the fin structure 104b-2, a third pair of source/drain regions 106b may be located at opposing ends of the fin structure 104b-3, and so on.

The flow of electrons to and/or from the qubit regions at the intersection points 116 of the fin grid 104 may be controlled using the gate structures 108a and/or 108b. Each gate structure 108a, of at least a subset of the gate structures 108a, is located between adjacent pairs of intersection points 116 (e.g., adjacent pairs of qubit regions) in the x-direction. Each gate structure 108b, of at least a subset of the gate structures 108b, is located between adjacent pairs of intersection points 116 (e.g., adjacent pairs of qubit regions) in the y-direction.

For example, a gate structure 108a may be located between a first intersection point 116, between the fin structure 104a-1 and the fin structure 104b-1, and a second intersection point 116 between the fin structure 104a-1 and the fin structure 104b-2; another gate structure 108a may be located between a first intersection point 116, between the fin structure 104a-1 and the fin structure 104b-2, and a second intersection point 116 between the fin structure 104a-1 and the fin structure 104b-3; and so on. Similarly for the other fin structures 104a-2 through 104a-n. The gate structures 108a on the fin structure 104a-1 may control the flow of electrons to and/or from the qubit regions at the intersection points 116 between the fin structure 104a-1 and the fin structures 104b-1 through 104b-m. Similarly for the other fin structures 104a-2 through 104a-n. Moreover, a gate structure 108a located between a source/drain region 106a at an end of the fin structure 104a-1 and the intersection point 116 of the fin structure 104a-1 and the fin structure 104b-m may be configured to control the flow of electrons to the source/drain region 106a at the end of the fin structure 104-a. Similarly for the other fin structures 104a-2 through 104a-n.

As further shown in FIG. 1B, a gate structure 108b may be located between a first intersection point 116, between the fin structure 104b-1 and the fin structure 104a-1, and a second intersection point 116 between the fin structure 104b-1 and the fin structure 104a-n; another gate structure 108b may be located between a first intersection point 116, between the fin structure 104b-2 and the fin structure 104a-1, and a second intersection point 116 between the fin structure 104b-2 and the fin structure 104a-n; and so on. The gate structures 108b on the fin structure 104b-1 may control the flow of electrons to and/or from the qubit regions at the intersection points 116 between the fin structure 104b-1 and the fin structures 104a-1 through 104a-n. Similarly for the other fin structures 104b-2 through 104b-m. Moreover, a gate structure 108a located between a source/drain region 106b at an end of the fin structure 104b-1 and the intersection point 116 of the fin structure 104b-1 and the fin structure 104a-n may be configured to control the flow of electrons to the source/drain region 106b at the end of the fin structure 104b-1. Similarly for the other fin structures 104b-2 through 104b-m.

As indicated above, FIGS. 1A and 1B are provided as an example. Other examples may differ from what is described with regard to FIGS. 1A and 1B.

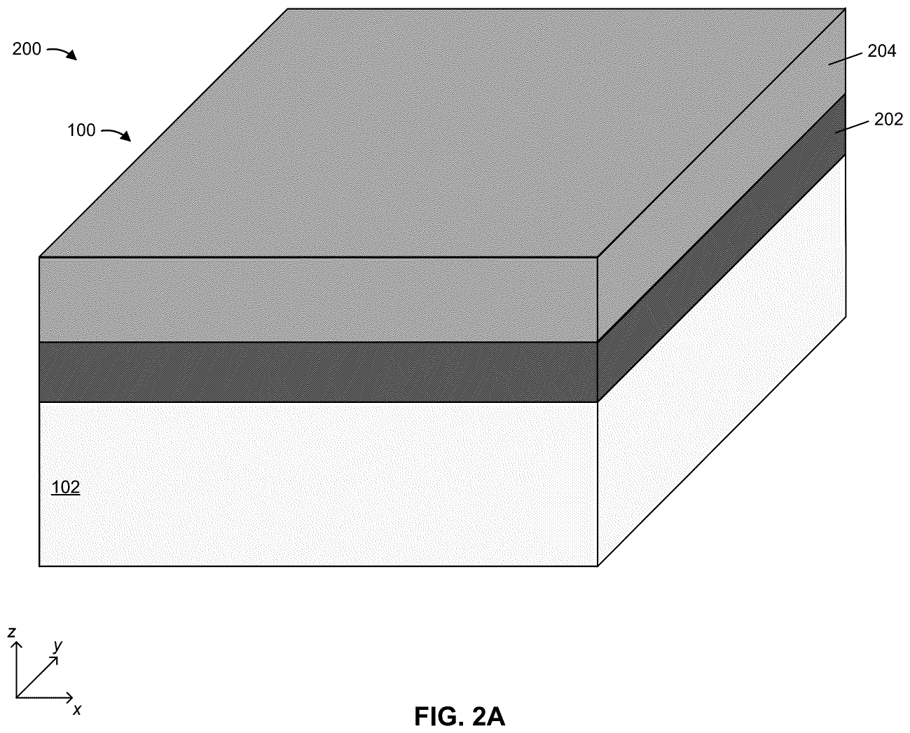

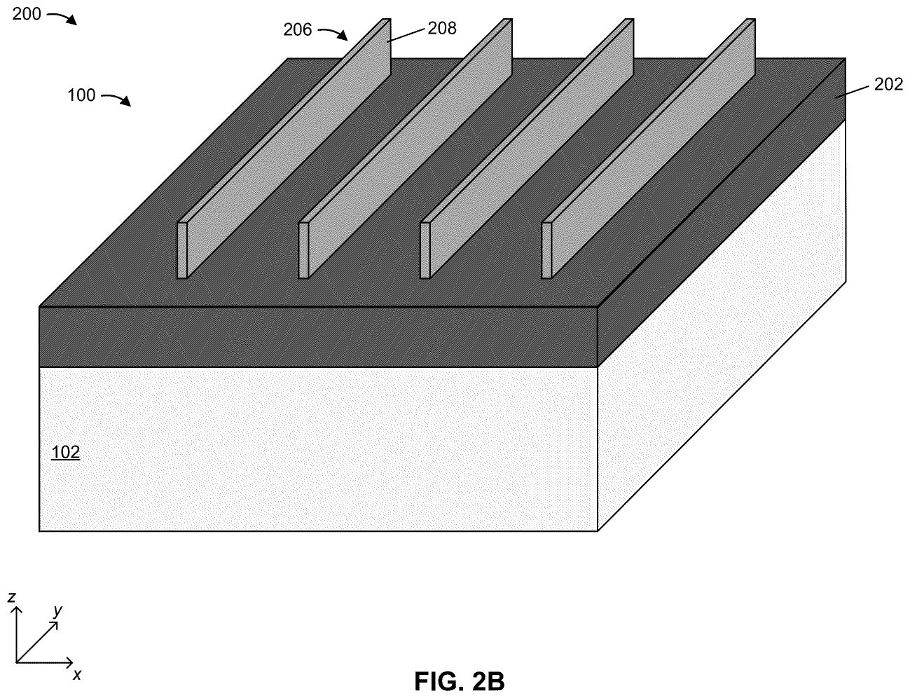

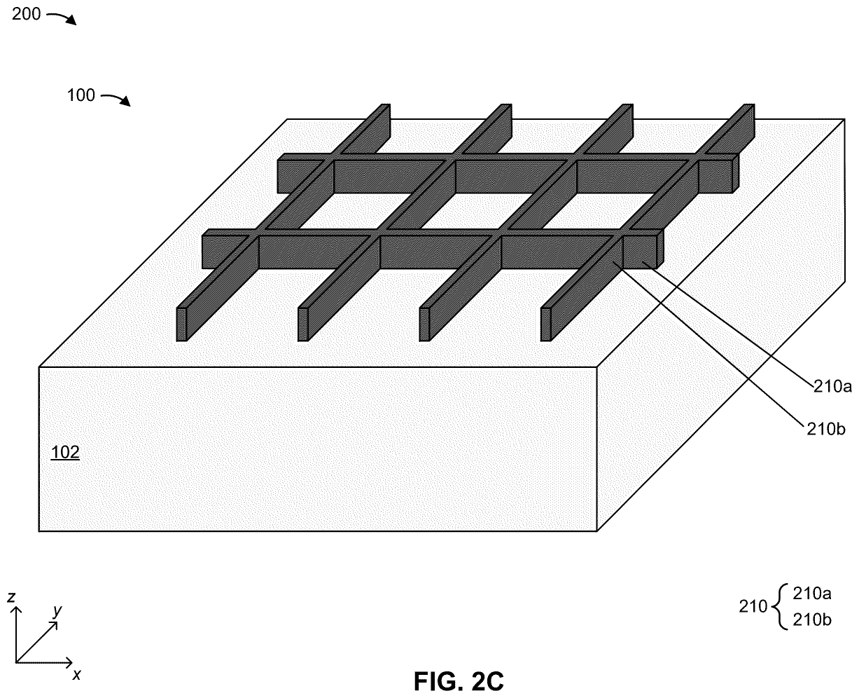

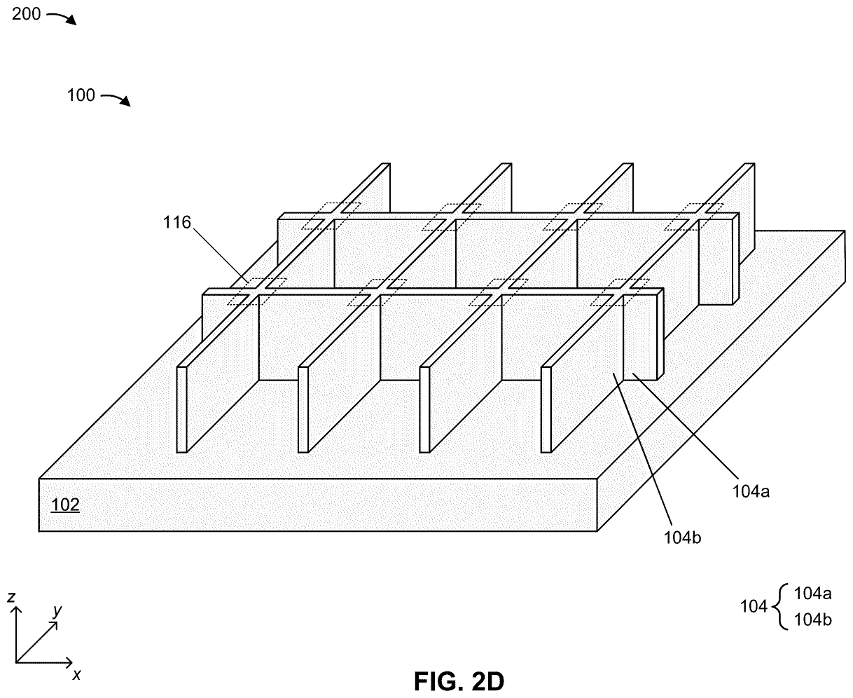

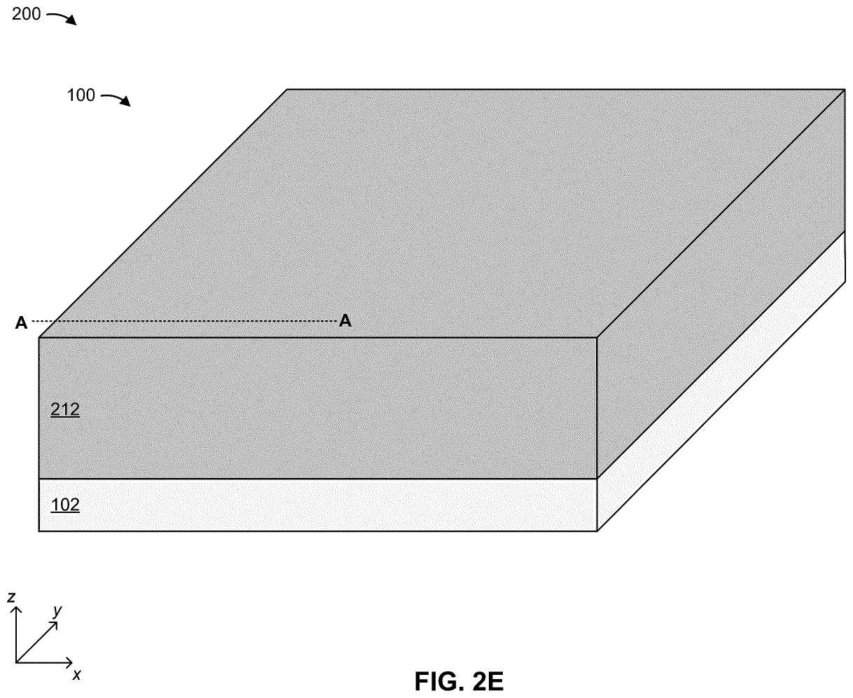

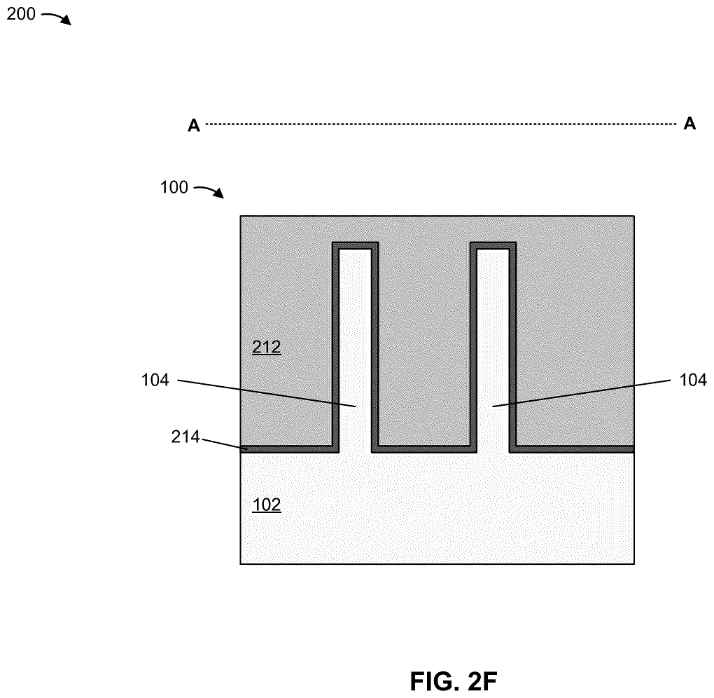

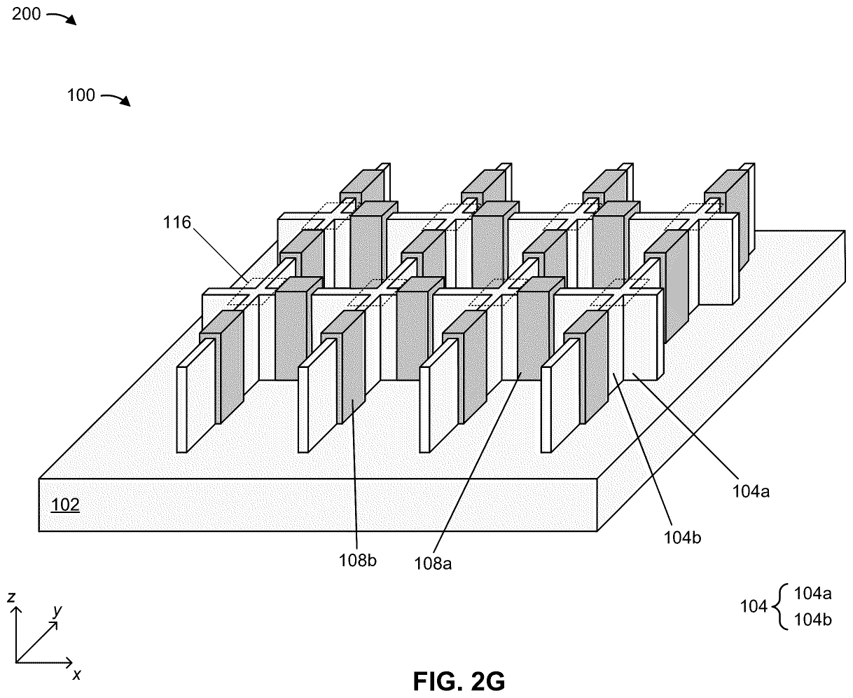

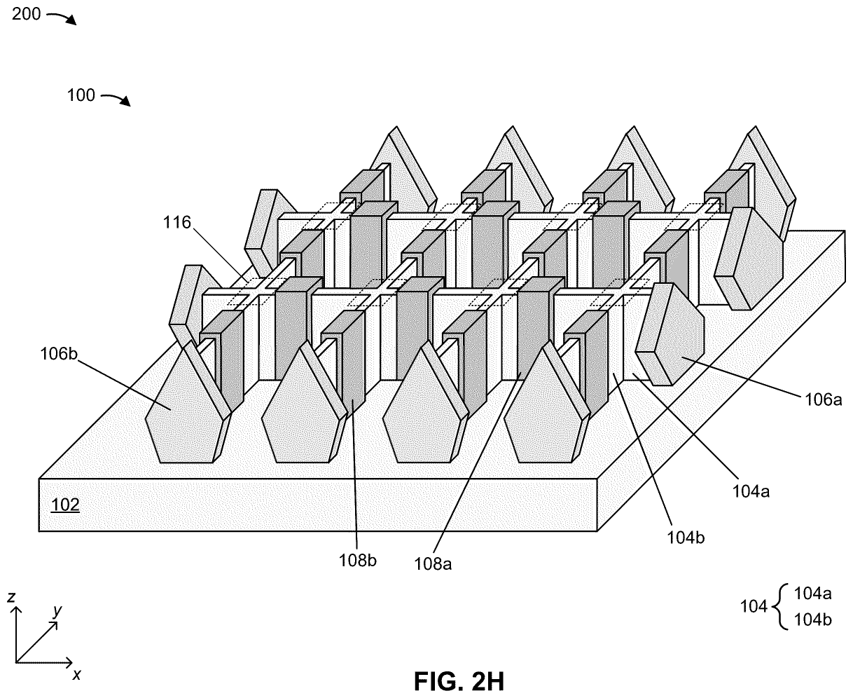

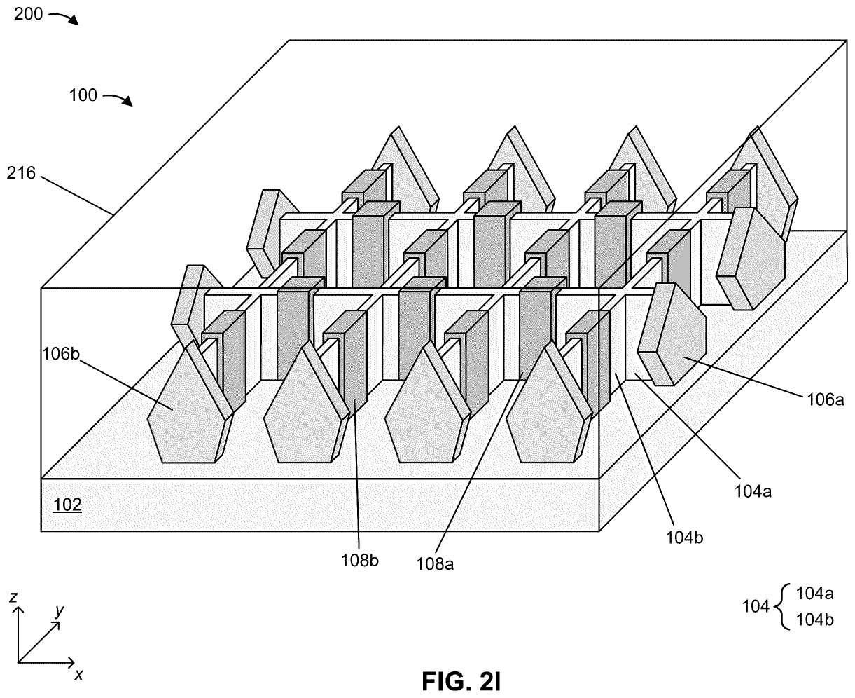

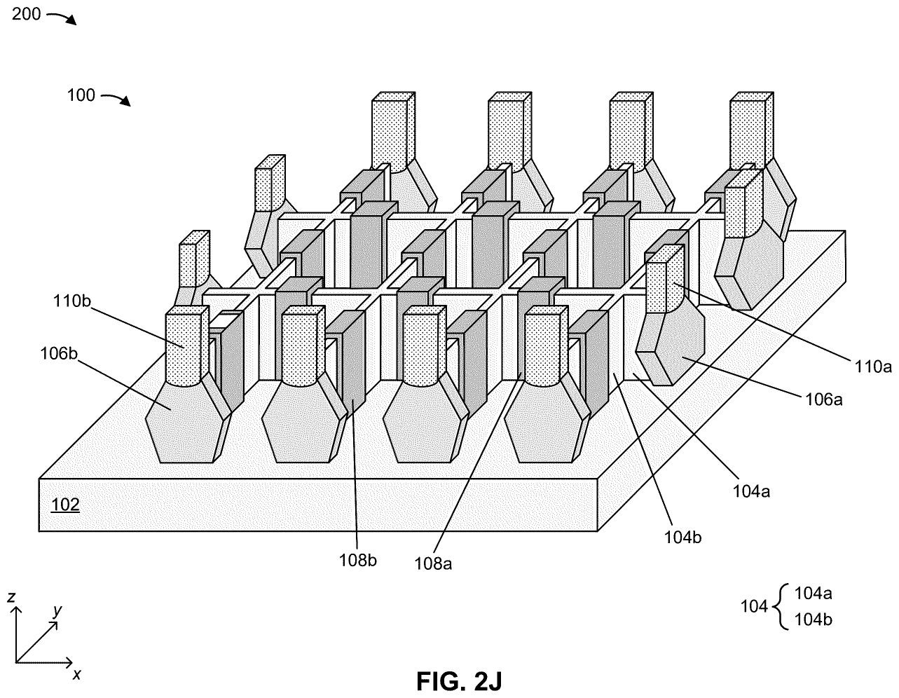

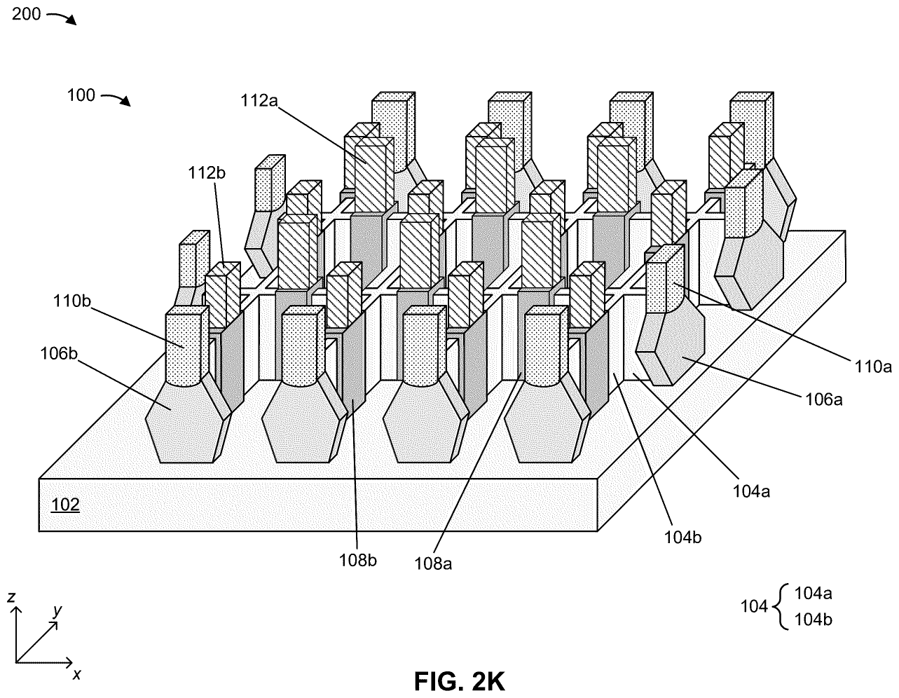

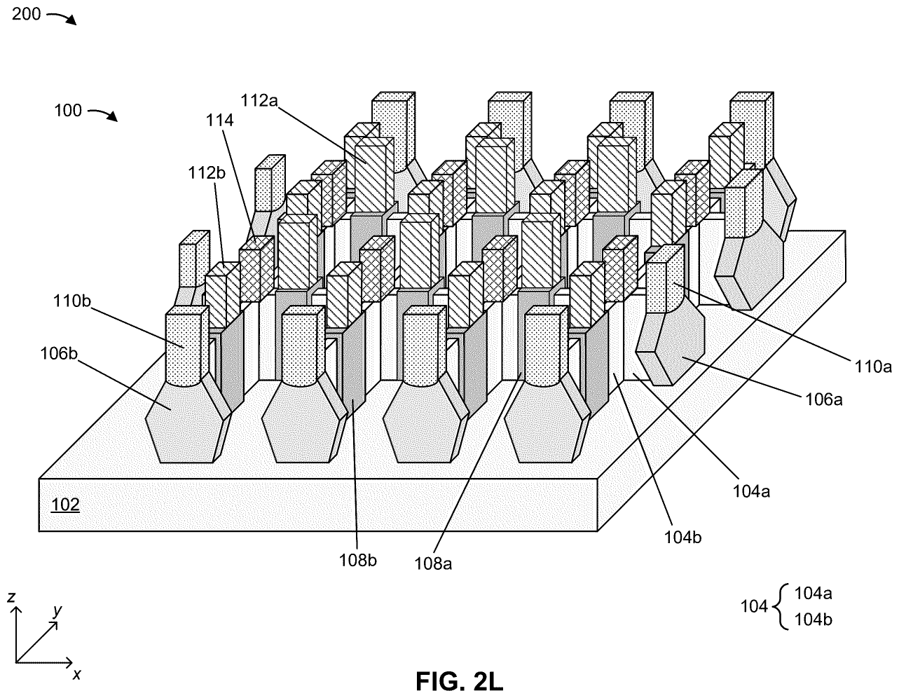

FIGS. 2A-2L are diagrams of an example 200 of forming the quantum computing semiconductor device 100 described herein. In some implementations, one or more semiconductor processing tools may be used to perform one or more of the semiconductor processing operations described in connection with FIGS. 2A-2L, such as a deposition tool, an exposure tool, a developer tool, an etch tool, an ion implantation tool, and/or a wafer/die transport tool, among other examples.

Turning to FIG. 2A, the substrate 102 may be provided. The substrate 102 may be provided in the form of a semiconductor wafer such as a silicon (Si) wafer, a semiconductor die, and/or another type of substrate on which semiconductor devices may be formed.

As further shown in FIG. 2A, a patterning stack may be formed on the substrate 102. The patterning stack may include a plurality of masking layers, including a masking layer 202 on the substrate 102, and a masking layer 204 on the masking layer 202. In some implementations, the masking layer 202 and the masking layer 204 are formed of different materials to enable the masking layer 202 and the masking layer 204 to be patterned independently of each other. For example, the masking layer 202 may include a silicon oxide material (e.g., SiOₓ such as SiO₂) and the masking layer 204 may include a silicon nitride material (e.g., SiₓN_{y} such as Si₃N₄). This enables the masking layer 204 to be etched while the masking layer 202 functions as an etch stop layer for the masking layer 204.

A deposition tool may be used to deposit each of the masking layer 202 and the masking layer 204, using a physical vapor deposition (PVD) technique, an atomic layer deposition (ALD) technique, a chemical vapor deposition (CVD) technique, an oxidation technique, and/or another suitable deposition technique. In some implementations, a planarization tool is used to perform a chemical mechanical planarization (CMP) operation or another type of planarization to planarize the masking layer 202 and/or the masking layer 204 after the masking layer 202 and/or the masking layer 204 are deposited.

As shown in FIG. 2B, a first pattern 206 may be formed in the masking layer 204. The first pattern 206 may include a plurality of mandrels 208. The mandrels 208 include elongated dielectric fins that extend in the y-direction in the quantum computing semiconductor device 100. In some implementations, a pattern in a photoresist layer is used to etch the masking layer 204 to form the first pattern 206 in the masking layer 204. In these implementations, a deposition tool may be used to form the photoresist layer on the masking layer 204 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the masking layer 204 based on the pattern to form the first pattern 206 in the masking layer 204. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 2C, a second pattern 210 may be formed in the masking layer 202. The second pattern 210 may be formed using the first pattern 206 in the masking layer 204 to etch the masking layer 202. The second pattern 210 includes a first plurality of mandrels 210a extending in the x-direction in the quantum computing semiconductor device 100, and a second plurality of mandrels 210b extending in the y-direction in the quantum computing semiconductor device 100. In other words, the first plurality of mandrels 210a extend in a first direction in the quantum computing semiconductor device 100, and the second plurality of mandrels 210b extend in a second direction in the quantum computing semiconductor device 100, where the second direction is approximately perpendicular to the first direction.

The second pattern 210 may be formed using a double patterning technique. For example, the first plurality of mandrels 210a may be formed using lithography patterning techniques similar to those used for the mandrels 208 of the first pattern 206, and the second plurality of mandrels 210b may be formed based on the mandrels 208 in the first pattern 206. To form the first plurality of mandrels, a pattern in a photoresist layer is used to etch the masking layer 202. In these implementations, a deposition tool may be used to form the photoresist layer on the masking layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

The masking layer 202 may then be etched (e.g., using an etch tool) based on the pattern in the photoresist layer and based on the mandrels 208 of the first pattern 206 to form the second pattern 210. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, the mandrels 208 of the first pattern 206 are removed by etching, by CMP, and/or by another suitable technique.

As shown in FIG. 2D, the fin grid 104 may be formed in the substrate 102 using the second pattern 210 in the masking layer 202. For example, the substrate 102 may be etched (e.g., using an etch tool) based on the second pattern 210 in the masking layer 202. In some implementations, the etch operation includes a plasma etch operation, a wet chemical etch operation, and/or another type of etch operation. Etching the substrate 102 based on the second pattern 210 includes etching the substrate 102 based on the first plurality of mandrels 210a to form the fin structures 104a in the substrate 102, and etching the substrate 102 based on the second plurality of mandrels 210b to form the fin structures 104b in the substrate 102. The fin structures 104a and the fin structures 104b are formed in the substrate 102 such that fin structures 104a extend in a first direction (e.g., the x-direction) in the quantum computing semiconductor device 100, and the fin structures 104b extend in a section direction (e.g., the y-direction) in the quantum computing semiconductor device 100, where the first direction and the second direction are approximately perpendicular.

As shown in FIG. 2E, a gate electrode layer 212 is formed over the substrate 102 and over the fin grid 104. In some implementations, shallow trench isolation (STI) regions may be formed around the fin grid 104 prior to formation of the gate electrode layer 212. The STI regions may be formed by depositing an STI layer, planarizing the STI layer, and then etching the STI layer to form the STI regions. In some implementations, the remaining portions of the first pattern 206 and/or the remaining portions of the second pattern 210 may be removed during the planarization of the STI layer.

FIG. 2F illustrates a cross-section view of the gate electrode layer 212 along the line A-A in FIG. 2E. As shown in FIG. 2F, a gate dielectric layer 214 may be formed on the fin grid 104 (including the fin structures 104a and the fin structures 104b), and the gate electrode layer 212 may be formed on the gate dielectric layer 214 over the fin grid 104. The gate dielectric layer 214 may be conformally deposited using a CVD technique, an ALD technique, and/or another suitable depositing technique. The gate electrode layer 212 may be blanket deposited using a CVD technique, a PVD technique, and/or another suitable deposition technique.

The gate electrode layer 212 may include a polysilicon material, a polysilicon material doped with one or more types of dopants (e.g., p-type dopants, n-type dopants), a metal-containing material (e.g., tungsten (W), titanium (Ti), titanium nitride (TiN), aluminum (Al)), and/or another suitable gate electrode material. The gate dielectric layer 214 may include one or more dielectric materials. For example, the gate dielectric layer 214 may include a silicon oxide material (e.g., SiOₓ such as SiO₂). As another example, the gate dielectric layer 214 may include a high dielectric constant (high-k) dielectric material such as a silicon nitride material (e.g., SiₓN_{y} such as Si₃N₄), a hafnium oxide material (e.g., HfOₓ such as HfO₂), and/or an aluminum oxide material (AlₓO_{y} such as Al₂O₃), among other examples.

As shown in FIG. 2G, the gate electrode layer 212 and the gate dielectric layer 214 may be etched to form the gate structures 108a on the fin structures 104a, and to form the gate structures 108b on the fin structures 104b. Each gate structure 108a may wrap around at least three sides of a fin structure 104a, and each gate structure 108b may wrap around at least three sides of a fin structure 104b. The gate dielectric layer 214 (not shown for purposes of clarity) may be included between the gate structures 108a and the fin structures 104a, and between the gate structures 108b and the fin structures 104b.

In some implementations, a pattern in a photoresist layer is used to etch the gate electrode layer 212 to form the gate structures 108a and the gate structures 108b. In these implementations, a deposition tool may be used to form the photoresist layer on the gate electrode layer 212 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the gate electrode layer 212 based on the pattern to form the gate structures 108a and the gate structures 108b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the gate structures 108a and the gate structures 108b from the gate electrode layer 212.

The gate structures 108a may be formed such that each set of a plurality of sets of gate structures 108a is formed on respective fin structure 104a. For example, a first set of gate structures 108a may be formed on a first fin structure 104a, a second set of gate structures 108a may be formed on a second fin structure 104a, and so on. One or more of the gate structures 108a formed on a fin structure 104a may be located between a first intersection point 116 between the fin structure 104a and a first fin structure 104b and a second intersection point 116 between the fin structure 104a and a second fin structure 104b. In other words, one or more of the gate structures 108a formed on a fin structure 104a may be located between adjacent intersection points 116 between the fin structure 104a and two of the fin structures 104b. In some implementations, one or more of the gate structures 108a formed on a fin structure 104a are located between an intersection point 116 and an end of the fin structure 104a.

The gate structures 108b may be formed such that each set of a plurality of sets of gate structures 108b is formed on a respective fin structure 104b. For example, a first set of gate structures 108b may be formed on a first fin structure 104b, a second set of gate structures 108b may be formed on a second fin structure 104b, and so on. One or more of the gate structures 108b formed on a fin structure 104b may be located between a first intersection point 116 between the fin structure 104b and a first fin structure 104a and a second intersection point 116 between the fin structure 104b and a second fin structure 104a. In other words, one or more of the gate structures 108b formed on a fin structure 104b may be located between adjacent intersection points 116 between the fin structure 104b and two of the fin structures 104a. In some implementations, one or more of the gate structures 108b formed on a fin structure 104b are located between an intersection point 116 and an end of the fin structure 104b.

As shown in FIG. 2H, the source/drain regions 106a are formed at ends of the fin structures 104a, and the source/drain regions 106b are formed at ends of the fin structures 104b. A deposition tool may be used to form the source/drain regions 106a and 106b in an epitaxial growth operation in which layers of the epitaxial material are deposited such that the layers are formed in a particular crystalline orientation. Additionally and/or alternatively, the source/drain regions 106a and 106b may be formed using a CVD technique and/or another suitable deposition technique. In some implementations, the source/drain regions 106a and/or 106b are doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial growth operation. Examples of p-type dopants that may be used in the epitaxial operation include boron (B) or germanium (Ge), among other examples. Examples of n-type dopants that may be used in the epitaxial operation include phosphorous (P) or arsenic (As), among other examples.

In some implementations, the source/drain regions 106a are formed adjacent to the ends of the fin structures 104a such that the source/drain regions 106a are formed on the substrate 102 and/or on the STI regions around the fin structures 104a. In some implementations, the source/drain regions 106a are formed on the ends of the fin structures 104a. For example, the ends of the fin structures 104a may be etched (e.g., using an etch tool) to form source/drain recesses in the ends of the fin structures 104a, and the source/drain regions 106a may be formed on the ends of the fin structures 104a in the source/drain recesses.

In some implementations, the source/drain regions 106b are formed adjacent to the ends of the fin structures 104b such that the source/drain regions 106b are formed on the substrate 102 and/or on the STI regions around the fin structures 104b. In some implementations, the source/drain regions 106b are formed on the ends of the fin structures 104b. For example, the ends of the fin structures 104b may be etched to form source/drain recesses in the ends of the fin structures 104b, and the source/drain regions 106b may be formed on the ends of the fin structures 104b in the source/drain recesses.

The source/drain regions 106a are formed such that a pair of source/drain regions 106a is located at opposing ends of a fin structure 104a. The source/drain regions 106a located at first ends of the fin structures 104a may correspond to input regions to the quantum computing array of the quantum computing semiconductor device 100, and the source/drain region 106a located at second ends of the fin structures 104a opposing the first ends may correspond to accumulation regions of the quantum computing array of the quantum computing semiconductor device 100. The source/drain regions 106a located at the first ends of the fin structures 104a (e.g., the input regions) may be configured to provide electrons to qubit regions located at the intersection points 116 along the fin structures 104a, and source/drain regions 106a located at the second ends of the fin structures 104a (e.g., the accumulation regions) may be configured to measure or sample the charge (and the associated spin) of the qubit regions located at the intersection points 116 along the fin structures 104a.

The source/drain regions 106b are formed such that a pair of source/drain regions 106b is located at opposing ends of a fin structure 104b. The source/drain regions 106b located at first ends of the fin structures 104b may correspond to input regions to the quantum computing array of the quantum computing semiconductor device 100, and the source/drain region 106b located at second ends of the fin structures 104b opposing the first ends may correspond to accumulation regions of the quantum computing array of the quantum computing semiconductor device 100. The source/drain regions 106b located at the first ends of the fin structures 104b (e.g., the input regions) may be configured to provide electrons to qubit regions located at the intersection points 116 along the fin structures 104b, and source/drain regions 106b located at the second ends of the fin structures 104b (e.g., the accumulation regions) may be configured to measure or sample the charge (and the associated spin) of the qubit regions located at the intersection points 116 along the fin structures 104b.

As shown in FIG. 2I, an interlayer dielectric (ILD) layer 216 may be formed over the fin grid 104, over the source/drain regions 106a and 106b, and/or over the gate structures 108a and 108b. The ILD layer 216 may include one or more layers of dielectric material, such as a silicon oxide (SiOₓ), a silicon nitride (SiₓN_{y}), a silicon oxynitride (SiON), fluoride-doped silicate glass (FSG), silicon carbon nitride (SiCN), and/or another suitable dielectric material. In some implementations, an etch stop layer (ESL) is formed prior to formation of the ILD layer 216. A deposition tool may be used to deposit the ILD layer 216 using a PVD technique, an ALD technique, a CVD technique, an oxidation technique, and/or another suitable deposition technique. The ILD layer 216 may be deposited in one or more deposition operations. In some implementations, a planarization tool may be used to planarize the ILD layer 216 after the ILD layer 216 is deposited.

As shown in FIG. 2J, the source/drain contacts 110a may be formed on the source/drain regions 106a, and the source/drain contacts 110b may be formed on the source/drain region 106b. The source/drain contacts 110a and 110b may be formed in recesses in the ILD layer 216 (which is not shown in FIG. 2J for purposes of clarity).

In some implementations, a pattern in a photoresist layer is used to etch the ILD layer 216 to form the recesses for the source/drain contacts 110a and 110b. In these implementations, a deposition tool may be used to form the photoresist layer on the ILD layer 216 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 216 based on the pattern to form the recesses in the ILD layer 216 over the source/drain regions 106a and 106b. In some implementations, the etch tool is used to etch through the ILD layer 216 and into a portion of the source/drain regions 106a and 106b such that the recesses extend into portions of the source/drain regions 106a and 106b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses in the ILD layer 216.

A deposition tool may be used to deposit the source/drain contacts 110a and 110b using a CVD technique, a PVD technique, an ALD technique, an electroplating technique, and/or another suitable deposition technique. In some implementations, one or more additional layers are formed in the recesses prior to formation of the source/drain contacts 110a and 110b. As an example, a metal silicide layer (e.g., titanium silicide (TiSiₓ) or another metal silicide layer) may be formed on the top surfaces of the source/drain regions 106a and/or on the top surfaces of the source/drain regions 106b prior to formation of the source/drain contacts 110a and/or 110b. As another example, one or more barrier layers may be formed on the bottom surfaces and/or on the sidewalls in the recesses prior to formation of the source/drain contacts 110a and/or 110b. As another example, one or more adhesion layers may be formed on the bottom surfaces and/or on the sidewalls in the recesses prior to formation of the source/drain contacts 110a and/or 110b. In some implementations, a planarization tool is used to planarize the source/drain contacts 110a and/or 110b after the source/drain contacts 110a and/or 110b are deposited.

As shown in FIG. 2K, the gate contacts 112a may be formed on the gate structures 108a, and the gate contacts 112b may be formed on the gate structures 108b. The gate contacts 112a and 112b may be formed in recesses in the ILD layer 216 (which is not shown in FIG. 2K for purposes of clarity).

In some implementations, a pattern in a photoresist layer is used to etch the ILD layer 216 to form the recesses for the gate contacts 112a and 112b. In these implementations, a deposition tool may be used to form the photoresist layer on the ILD layer 216 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 216 based on the pattern to form the recesses in the ILD layer 216 over the gate structures 108a and 108b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses in the ILD layer 216.

A deposition tool may be used to deposit the gate contacts 112a and 112b using a CVD technique, a PVD technique, an ALD technique, an electroplating technique, and/or another suitable deposition technique. In some implementations, one or more additional layers are formed in the recesses prior to formation of the gate contacts 112a and 112b. As an example, one or more barrier layers may be formed on the bottom surfaces and/or on the sidewalls in the recesses prior to formation of the gate contacts 112a and/or 112b. As another example, one or more adhesion layers may be formed on the bottom surfaces and/or on the sidewalls in the recesses prior to formation of the gate contacts 112a and/or 112b. In some implementations, a planarization tool is used to planarize the gate contacts 112a and/or 112b after the gate contacts 112a and/or 112b are deposited.

As shown in FIG. 2L, the plunger contacts 114 may be formed on the intersection points 116 of the fin grid 104. The plunger contacts 114 may be formed in recesses in the ILD layer 216 (which is not shown in FIG. 2L for purposes of clarity).

In some implementations, a pattern in a photoresist layer is used to etch the ILD layer 216 to form the recesses for the plunger contacts 114. In these implementations, a deposition tool may be used to form the photoresist layer on the ILD layer 216 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 216 based on the pattern to form the recesses in the ILD layer 216 over the intersection points 116 of the fin grid 104. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses in the ILD layer 216.

A deposition tool may be used to deposit the plunger contacts 114 using a CVD technique, a PVD technique, an ALD technique, an electroplating technique, and/or another suitable deposition technique. In some implementations, one or more additional layers are formed in the recesses prior to formation of the plunger contacts 114. As an example, one or more barrier layers may be formed on the bottom surfaces and/or on the sidewalls in the recesses prior to formation of the plunger contacts 114. As another example, one or more adhesion layers may be formed on the bottom surfaces and/or on the sidewalls in the recesses prior to formation of the plunger contacts 114. In some implementations, a planarization tool is used to planarize the plunger contacts 114 after the plunger contacts 114 are deposited.

In some implementations, the source/drain contacts 110a and 110b are formed prior to formation of the gate contacts 112a and 112b, and prior to formation of the plunger contacts 114. In some implementations, the source/drain contacts 110a and 110b are formed after formation of the gate contacts 112a and 112b, and prior to formation of the plunger contacts 114. In some implementations, the source/drain contacts 110a and 110b are formed after formation of the gate contacts 112a and 112b, and after formation of the plunger contacts 114. In some implementations, the gate contacts 112a and 112b are formed prior to formation of the plunger contacts 114. In some implementations, the gate contacts 112a and 112b are formed after formation of the plunger contacts 114. In some implementations, the source/drain contacts 110a and 110b, and the gate contacts 112a and 112b, are formed during the same one or more deposition operations. In some implementations, the source/drain contacts 110a and 110b, and the plunger contacts 114, are formed during the same one or more deposition operations. In some implementations, the gate contacts 112a and 112b, and the plunger contacts 114 are formed during the same one or more deposition operations. In some implementations, the source/drain contacts 110a and 110b, the gate contacts 112a and 112b, and the plunger contacts 114 are formed during the same one or more deposition operations.

As indicated above, FIGS. 2A-2L are provided as an example. Other examples may differ from what is described with regard to FIGS. 2A-2L.

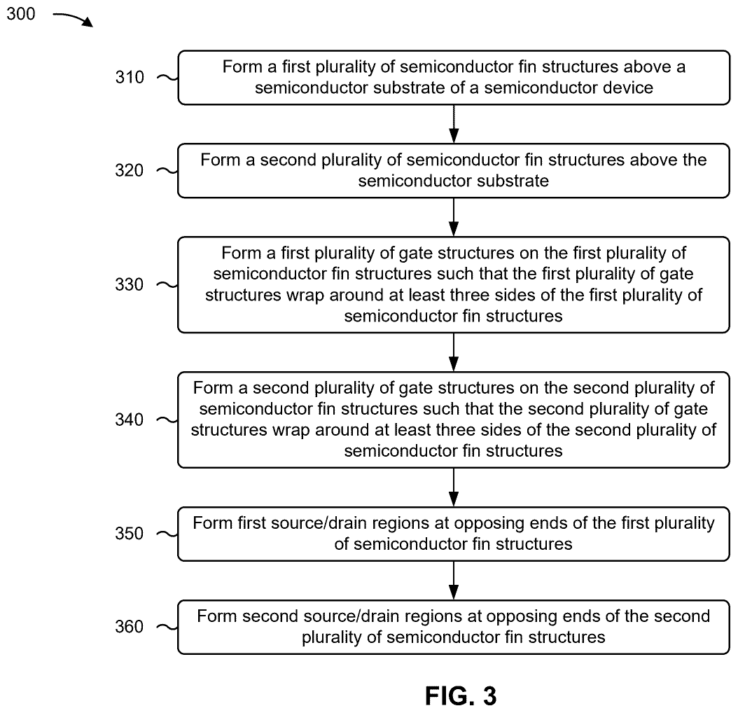

FIG. 3 is a flowchart of an example process 300 associated with forming a quantum computing semiconductor device described herein. In some implementations, one or more process blocks of FIG. 3 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 3, process 300 may include forming a first plurality of semiconductor fin structures above a semiconductor substrate of a semiconductor device (block 310). For example, one or more semiconductor processing tools may be used to form a first plurality of semiconductor fin structures (e.g., the fin structures 104a) above a semiconductor substrate (e.g., the substrate 102) of a semiconductor device (e.g., the quantum computing semiconductor device 100), as described herein. In some implementations, the first plurality of semiconductor fin structures extend in a first direction (e.g., the x-direction) in the semiconductor device and are arranged in a second direction (e.g., the y-direction) in the semiconductor device approximately perpendicular to the first direction.

As further shown in FIG. 3, process 300 may include forming a second plurality of semiconductor fin structures above the semiconductor substrate (block 320). For example, one or more semiconductor processing tools may be used to form a second plurality of semiconductor fin structures (e.g., fin structure 104b) above the semiconductor substrate, as described herein. In some implementations, the second plurality of semiconductor fin structures extend in the second direction and are arranged in the first direction.

As further shown in FIG. 3, process 300 may include forming a first plurality of gate structures on the first plurality of semiconductor fin structures such that the first plurality of gate structures wrap around at least three sides of the first plurality of semiconductor fin structures (block 330). For example, one or more semiconductor processing tools may be used to form a first plurality of gate structures (e.g., the gate structures 108a) on the first plurality of semiconductor fin structures such that the first plurality of gate structures wrap around at least three sides of the first plurality of semiconductor fin structures, as described herein.

As further shown in FIG. 3, process 300 may include forming a second plurality of gate structures on the second plurality of semiconductor fin structures such that the second plurality of gate structures wrap around at least three sides of the second plurality of semiconductor fin structures (block 340). For example, one or more semiconductor processing tools may be used to form a second plurality of gate structures (e.g., the gate structures 108b) on the second plurality of semiconductor fin structures such that the second plurality of gate structures wrap around at least three sides of the second plurality of semiconductor fin structures, as described herein.

As further shown in FIG. 3, process 300 may include forming first source/drain regions at opposing ends of the first plurality of semiconductor fin structures (block 350). For example, one or more semiconductor processing tools may be used to form first source/drain regions (e.g., the source/drain regions 106a) at opposing ends of the first plurality of semiconductor fin structures, as described herein.

As further shown in FIG. 3, process 300 may include forming second source/drain regions at opposing ends of the second plurality of semiconductor fin structures (block 360). For example, one or more semiconductor processing tools may be used to form second source/drain regions (e.g., the source/drain regions 106b) at opposing ends of the second plurality of semiconductor fin structures, as described herein.

Process 300 may include additional implementations, such as any single implementation or any combination of implementations described below and/or in connection with one or more other processes described elsewhere herein.

In a first implementation, forming the first plurality of semiconductor fin structures and the second plurality of semiconductor fin structures includes forming a first pattern (e.g., the first pattern 206) in a first masking layer (e.g., the masking layer 204), forming a second pattern (e.g., the second pattern 210) in a second masking layer (e.g., the masking layer 202) using the first pattern in the first masking layer, and forming the first plurality of semiconductor fin structures and the second plurality of semiconductor fin structures using the second pattern in the second masking layer.

In a second implementation, alone or in combination with the first implementation, the first pattern includes a first plurality of mandrels (e.g., the mandrels 208) extending in the second direction and arranged in the first direction, and the second pattern comprises a second plurality of mandrels (e.g., the mandrels 210a) extending in the first direction and arranged in the second direction.

In a third implementation, alone or in combination with one or more of the first and second implementations, the second pattern further includes a third plurality of mandrels (e.g., the mandrels 210b) extending in the second direction and arranged in the first direction, and the second plurality of mandrels intersect with the third plurality of mandrels.

In a fourth implementation, alone or in combination with one or more of the first through third implementations, forming the first plurality of gate structures and the second plurality of gate structures includes forming a gate dielectric layer (e.g., the gate dielectric layer 214) on the first plurality of semiconductor fin structures and on the second plurality of semiconductor fin structures, forming a gate electrode layer (e.g., the gate electrode layer 212) on the gate dielectric layer, and etching the gate dielectric layer and the gate electrode layer to form the first plurality of gate structures and the second plurality of gate structures.

In a fifth implementation, alone or in combination with one or more of the first through fourth implementations, process 300 includes forming an ILD layer (e.g., the ILD layer 216) over the first plurality of semiconductor fin structures, the second plurality of semiconductor fin structures, the first plurality of gate structures, and the second plurality of gate structures, forming recesses in the ILD layer above the first plurality of gate structures and above the second plurality of gate structures, and forming, in the recesses, a first plurality of gate contacts (e.g., the gate contacts 112a) on the first plurality of gate structures and a second plurality of gate contacts (e.g., the gate contacts 112b) on the second plurality of gate structures.

In a sixth implementation, alone or in combination with one or more of the first through fifth implementations, process 300 includes forming other recesses in the ILD layer above intersection points (e.g., the intersection points 116) between the first plurality of semiconductor fin structures and the second plurality of semiconductor fin structures, and forming, in the other recesses, plunger contacts on the intersection points.

In a seventh implementation, alone or in combination with one or more of the first through sixth implementations, process 300 includes forming other recesses in the ILD layer above the first source/drain regions and above the second source/drain regions, and forming, in the other recesses, a first plurality of source/drain contacts (e.g., the source/drain contacts 110a) on the first source/drain regions and a second plurality of source/drain contacts (e.g., the source/drain contacts 110b) on the second source/drain regions.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

In this way, qubits in a quantum computing semiconductor device may be arranged in a two-dimensional array. The two-dimensional array may be implemented using fin-based semiconductor manufacturing techniques. For example, a first active semiconductor region (e.g., a first fin structure) may extend in a first direction and a second active semiconductor region (e.g., a second fin structure) may extend in a second direction. A qubit may be located an intersection point between the first active semiconductor region and the second semiconductor region. This enables qubits to be formed in a grid in the two-dimensional array, which provides greater qubit density and shorter distances between qubits (and thus, greater quantum computing performance) compared to one-dimensional (e.g., linear) qubit arrays. Moreover, implementing qubits using fin-based semiconductor manufacturing techniques enables quantum computing arrays to be integrated on the same semiconductor device as other complementary metal-oxide semiconductor (CMOS) integrated circuits.

As described in greater detail above, some implementations described herein provide a semiconductor device. The semiconductor device includes a substrate. The semiconductor device includes a fin grid, extending above the substrate, comprising, a first plurality of semiconductor fin structures extending in a first direction and arranged in a second direction a second plurality of semiconductor fin structures extending in the second direction and arranged in the first direction, where the first plurality of semiconductor fin structures intersect the second plurality of semiconductor fin structures at a plurality of intersection points. The semiconductor device includes a first plurality of gate structures on the first plurality of semiconductor fin structures. The semiconductor device includes a second plurality of gate structures on the second plurality of semiconductor fin structures.

As described in greater detail above, some implementations described herein provide a method. The method includes forming a first plurality of semiconductor fin structures above a semiconductor substrate of a semiconductor device, where the first plurality of semiconductor fin structures extend in a first direction in the semiconductor device and are arranged in a second direction in the semiconductor device approximately perpendicular to the first direction. The method includes forming a second plurality of semiconductor fin structures above the semiconductor substrate, where the second plurality of semiconductor fin structures extend in the second direction and are arranged in the first direction. The method includes forming a first plurality of gate structures on the first plurality of semiconductor fin structures such that the first plurality of gate structures wrap around at least three sides of the first plurality of semiconductor fin structures. The method includes forming a second plurality of gate structures on the second plurality of semiconductor fin structures such that the second plurality of gate structures wrap around at least three sides of the second plurality of semiconductor fin structures. The method includes forming first source/drain regions at opposing ends of the first plurality of semiconductor fin structures. The method includes forming second source/drain regions at opposing ends of the second plurality of semiconductor fin structures.

As described in greater detail above, some implementations described herein provide a quantum computing semiconductor device. The quantum computing semiconductor device includes a substrate. The quantum computing semiconductor device includes a first plurality of semiconductor fin structures above the substrate, where the first plurality of semiconductor fin structures extend in a first direction and are arranged in a second direction. The quantum computing semiconductor device includes a second plurality of semiconductor fin structures above the substrate, where the second plurality of semiconductor fin structures extend in the second direction and are arranged in the first direction. The quantum computing semiconductor device includes a plurality of qubit regions at intersection points between the first plurality of semiconductor fin structures and the second plurality of semiconductor fin structures. The quantum computing semiconductor device includes a first plurality of barrier gate structures on the first plurality of semiconductor fin structures. The quantum computing semiconductor device includes a second plurality of barrier gate structures on the second plurality of semiconductor fin structures. The quantum computing semiconductor device includes a plurality of plunger contacts on the plurality of qubit regions.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a fin grid, extending above the substrate, comprising:
a first plurality of semiconductor fin structures extending in a first direction and arranged in a second direction; and
a second plurality of semiconductor fin structures extending in the second direction and arranged in the first direction,
wherein the first plurality of semiconductor fin structures intersect the second plurality of semiconductor fin structures at a plurality of intersection points;
a first plurality of gate structures on the first plurality of semiconductor fin structures; and
a second plurality of gate structures on the second plurality of semiconductor fin structures.

2. The semiconductor device of claim 1, wherein two or more gate structures, of the first plurality of gate structures, is located on a same semiconductor fin structure of the first plurality of semiconductor fin structures; and
wherein each gate structure of the two or more gate structures is located between adjacent intersection points, of the plurality of intersection points, in the first direction.

3. The semiconductor device of claim 2, wherein another two or more gate structures, of the second plurality of gate structures, is located on a same semiconductor fin structure of the second plurality of semiconductor fin structures.

4. The semiconductor device of claim 3, wherein each gate structure of the other two or more gate structures is located between adjacent intersection points, of the plurality of intersection points, in the second direction.

5. The semiconductor device of claim 1, further comprising:
plunger contacts above the intersection points between the first plurality of semiconductor fin structures and the second plurality of semiconductor fin structures.

6. The semiconductor device of claim 1, further comprising:
a first plurality of gate contacts on the first plurality of gate structures; and
a second plurality of gate contacts on the second plurality of gate structures.

7. The semiconductor device of claim 1, further comprising:
first source/drain regions at opposing ends of each of the first plurality of semiconductor fin structures; and
second source/drain regions at opposing ends of each of the second plurality of semiconductor fin structures.

8. The semiconductor device of claim 7, further comprising:
first source/drain contacts on the first source/drain regions; and
second source/drain contacts on the second source/drain regions.

9. A method, comprising:
forming a first plurality of semiconductor fin structures above a semiconductor substrate of a semiconductor device,
wherein the first plurality of semiconductor fin structures extend in a first direction in the semiconductor device and are arranged in a second direction in the semiconductor device approximately perpendicular to the first direction;
forming a second plurality of semiconductor fin structures above the semiconductor substrate,
wherein the second plurality of semiconductor fin structures extend in the second direction and are arranged in the first direction;
forming a first plurality of gate structures on the first plurality of semiconductor fin structures such that the first plurality of gate structures wrap around at least three sides of the first plurality of semiconductor fin structures;
forming a second plurality of gate structures on the second plurality of semiconductor fin structures such that the second plurality of gate structures wrap around at least three sides of the second plurality of semiconductor fin structures;
forming first source/drain regions at opposing ends of the first plurality of semiconductor fin structures; and
forming second source/drain regions at opposing ends of the second plurality of semiconductor fin structures.

10. The method of claim 9, wherein forming the first plurality of semiconductor fin structures and the second plurality of semiconductor fin structures comprises:
forming a first pattern in a first masking layer;
forming a second pattern in a second masking layer using the first pattern in the first masking layer; and
forming the first plurality of semiconductor fin structures and the second plurality of semiconductor fin structures using the second pattern in the second masking layer.

11. The method of claim 10, wherein the first pattern comprises a first plurality of mandrels extending in the second direction and arranged in the first direction; and
wherein the second pattern comprises a second plurality of mandrels extending in the first direction and arranged in the second direction.

12. The method of claim 11, wherein the second pattern further comprises a third plurality of mandrels extending in the second direction and arranged in the first direction; and
wherein the second plurality of mandrels intersect with the third plurality of mandrels.

13. The method of claim 9, wherein forming the first plurality of gate structures and the second plurality of gate structures comprises:
forming a gate dielectric layer on the first plurality of semiconductor fin structures and on the second plurality of semiconductor fin structures;
forming a gate electrode layer on the gate dielectric layer; and
etching the gate dielectric layer and the gate electrode layer to form the first plurality of gate structures and the second plurality of gate structures.

14. The method of claim 9, further comprising:
forming an interlayer dielectric (ILD) layer over the first plurality of semiconductor fin structures, the second plurality of semiconductor fin structures, the first plurality of gate structures, and the second plurality of gate structures;
forming recesses in the ILD layer above the first plurality of gate structures and above the second plurality of gate structures; and
forming, in the recesses, a first plurality of gate contacts on the first plurality of gate structures and a second plurality of gate contacts on the second plurality of gate structures.

15. The method of claim 14, further comprising:
forming other recesses in the ILD layer above intersection points between the first plurality of semiconductor fin structures and the second plurality of semiconductor fin structures; and
forming, in the other recesses, plunger contacts on the intersection points.

16. The method of claim 14, further comprising:
forming other recesses in the ILD layer above the first source/drain regions and above the second source/drain regions; and
forming, in the other recesses, a first plurality of source/drain contacts on the first source/drain regions and a second plurality of source/drain contacts on the second source/drain regions.

17. A quantum computing semiconductor device, comprising:
a substrate;
a first plurality of semiconductor fin structures above the substrate,
wherein the first plurality of semiconductor fin structures extend in a first direction and are arranged in a second direction;
a second plurality of semiconductor fin structures above the substrate,
wherein the second plurality of semiconductor fin structures extend in the second direction and are arranged in the first direction;
a plurality of qubit regions at intersection points between the first plurality of semiconductor fin structures and the second plurality of semiconductor fin structures;
a first plurality of barrier gate structures on the first plurality of semiconductor fin structures;
a second plurality of barrier gate structures on the second plurality of semiconductor fin structures; and
a plurality of plunger contacts on the plurality of qubit regions.

18. The quantum computing semiconductor device of claim 17, wherein the plurality of qubit regions are arranged in a two-dimensional grid in the quantum computing semiconductor device.

19. The quantum computing semiconductor device of claim 17, wherein the first plurality of barrier gate structures are located between adjacent pairs of the plurality of qubit regions in the first direction; and
wherein the second plurality of barrier gate structures are located between adjacent pairs of the plurality of qubit regions in the second direction.

20. The quantum computing semiconductor device of claim 17, further comprising:
a first plurality of accumulation regions located at ends of the first plurality of semiconductor fin structures; and
a second plurality of accumulation regions located at ends of the second plurality of semiconductor fin structures.
